(19) United States
(12) Patent Application Publication
(10) Pub. No.: US 2025/0344491 A1
(43) Pub. Date: Nov. 6, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masaru FURUKAWA, Himeji Hyogo (JP)

(21) Appl. No.: 19/269,523

(22) Filed: Jul. 15, 2025

Related U.S. Application Data
(63) Continuation of application No. PCT/JP2024/004153, filed on Feb. 7, 2024.

(30) Foreign Application Priority Data
Sep. 15, 2023 (JP) 2023-150228

(51) Int. Cl. H10D 84/00; H10D 62/832

(52) U.S. Cl. CPC H10D 84/146; H10D 62/8325

(57) ABSTRACT

According to one embodiment, a semiconductor device includes first to third electrodes, first to fifth semiconductor members, and a first insulating member. The first semiconductor member is of a first conductivity type, and includes a first partial region, a second partial region, a third partial region, a fourth partial region, a fifth partial region, and a sixth partial region. The second semiconductor member is of a second conductivity type, and includes a first semiconductor region, a second semiconductor region, a third semiconductor region, and a fourth semiconductor region. The third semiconductor member is of the first conductivity type, and includes a first semiconductor portion and a second semiconductor portion. The fourth semiconductor member is of the second conductivity type. The fifth semiconductor member is of the second conductivity type. The third electrode includes a first conductive portion. The first insulating member includes a first insulating region.

### CROSS-REFERENCE TO RELATED APPLICATIONS

This is a continuation application of International Application PCT/JP2024/004153, filed on Feb. 7, 2024. This application also claims priority to Japanese Patent Application No. 2023-150228, filed on Sep. 15, 2023. The entire contents of which are incorporated herein by reference.

### FIELD

Embodiments described herein generally relate to a semiconductor device.

### BACKGROUND

For example, it is desired to improve the characteristics of semiconductor devices including Schottky barrier diodes and the like.

### BRIEF DESCRIPTION OF THE DRAWINGS

FIG. 1 is a schematic cross-sectional view illustrating a semiconductor device according to a first embodiment.

### DETAILED DESCRIPTION

According to one embodiment, a semiconductor device includes a first electrode, a second electrode, a third electrode, a first semiconductor member, a second semiconductor member, a third semiconductor member, a fourth semiconductor member, a fifth semiconductor member, and a first insulating member. The first semiconductor member is provided between the first electrode and the second electrode, and is of a first conductivity type. The first semiconductor member includes a first partial region, a second partial region, a third partial region, a fourth partial region, a fifth partial region, and a sixth partial region. A second direction from the third partial region to the second partial region crosses a first direction from the first electrode to the second electrode. The first partial region is provided between the third partial region and the second partial region in the second direction. A direction from the second partial region to the fourth partial region crosses the first direction. A direction from the first partial region to the fifth partial region is along the first direction. A direction from the fourth partial region to the sixth partial region is along the first direction. The sixth partial region is in Schottky contact with the second electrode. The second semiconductor member is of a second conductivity type. The second semiconductor member includes a first semiconductor region, a second semiconductor region, a third semiconductor region, and a fourth semiconductor region. A direction from the second partial region to the first semiconductor region is along the first direction. A direction from the third partial region to the third semiconductor region is along the first direction. The third semiconductor member is of the first conductivity type. The third semiconductor member includes a first semiconductor portion and a second semiconductor portion. The second semiconductor region is provided between the fifth partial region and the first semiconductor portion in the second direction. The fourth semiconductor region is provided between the second semiconductor portion and the fifth partial region in the second direction. The first semiconductor portion and the second semiconductor portion are electrically connected to the second electrode. The fourth semiconductor member is of the second conductivity type. The first semiconductor region is provided between the second partial region and the fourth semiconductor member in the first direction. The first semiconductor portion is provided between the second semiconductor region and the fourth semiconductor member in the second direction. The fourth semiconductor member is electrically connected to the second electrode. The fifth semiconductor member is of the second conductivity type. The third semiconductor region is provided between the third partial region and the fifth semiconductor member in the first direction. The second semiconductor portion is provided between the fifth semiconductor member and the fourth semiconductor region in the second direction. The fifth semiconductor member is electrically connected to the second electrode. A fifth impurity concentration of the second conductivity type in the fifth semiconductor member is lower than a fourth impurity concentration of the second conductivity type of the fourth semiconductor member. The third electrode includes a first conductive portion. The fifth partial region is provided between the first partial region and the first conductive portion in the first direction. The first insulating member includes a first insulating region. The first insulating region is provided between the fifth partial region and at least a portion of the first conductive portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

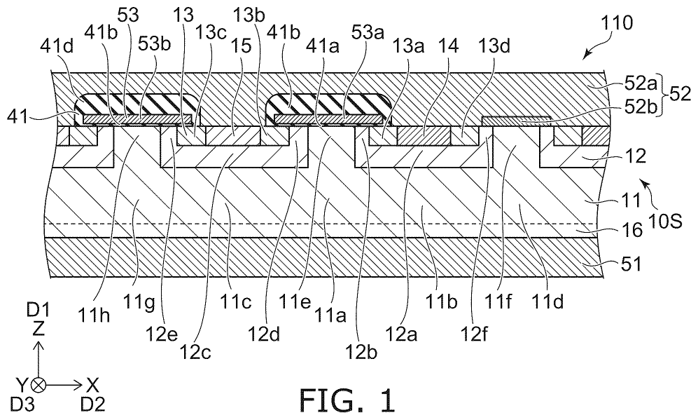

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a first semiconductor member 11, a second semiconductor member 12, a third semiconductor member 13, a fourth semiconductor member 14, and a fifth semiconductor member 15. The first semiconductor member 11, the second semiconductor member 12, the third semiconductor member 13, the fourth semiconductor member 14, and the fifth semiconductor member 15 are included in, for example, a semiconductor layer 10S.

The first semiconductor member 11 is provided between the first electrode 51 and the second electrode 52. The first semiconductor member 11 is of a first conductivity type. The first semiconductor member 11 includes a first partial region 11a, a second partial region 11b, a third partial region 11c, a fourth partial region 11d, a fifth partial region 11e, and a sixth partial region 11f. A second direction D2 from the third partial region 11c to the second partial region 11b crosses a first direction D1 from the first electrode 51 to the second electrode 52.

The first direction D1 is defined as a Z-axis direction. A direction perpendicular to the Z-axis direction is defined as an X-axis direction. A direction perpendicular to the Z-axis direction and the X-axis direction is defined as a Y-axis direction. In one example, the second direction D2 may be the X-axis direction.

The first partial region 11a is located between the third partial region 11c and the second partial region 11b in the second direction D2. A direction from the second partial region 11b to the fourth partial region 11d crosses the first direction D1. In this example, a direction from the second partial region 11b to the fourth partial region 11d is along the second direction D2. In the embodiment, a direction from the second partial region 11b to the fourth partial region 11d may be any direction crossing the first direction D1 (for example, a direction having a component such as the Y-axis direction).

A direction from the first partial region 11a to the fifth partial region 11e is along the first direction D1. A direction from the fourth partial region 11d to the sixth partial region 11f is along the first direction D1. The sixth partial region 11f makes Schottky contact with the second electrode 52.

The second semiconductor member 12 is of a second conductivity type. The first conductivity type is one of n-type and p-type. The second conductivity type is the other of n-type and p-type. In the following, it is assumed that the first conductivity type is n-type and the second conductivity type is p-type.

The second semiconductor member 12 includes a first semiconductor region 12a, a second semiconductor region 12b, a third semiconductor region 12c, and a fourth semiconductor region 12d. A direction from the second partial region 11b to the first semiconductor region 12a is along the first direction D1. A direction from the third partial region 11c to the third semiconductor region 12c is along the first direction D1.

The third semiconductor member 13 is of the first conductivity type. The third semiconductor member 13 includes a first semiconductor portion 13a and a second semiconductor portion 13b. The second semiconductor region 12b is located between the fifth partial region 11e and the first semiconductor portion 13a in the second direction D2. The fourth semiconductor region 12d is located between the second semiconductor portion 13b and the fifth partial region 11e in the second direction D2. The first semiconductor portion 13a and the second semiconductor portion 13b are electrically connected to the second electrode 52.

The fourth semiconductor member 14 is of the second conductivity type. The first semiconductor region 12a is provided between the second partial region 11b and the fourth semiconductor member 14 in the first direction D1. The first semiconductor portion 13a is provided between the second semiconductor region 12b and the fourth semiconductor member 14 in the second direction D2. The fourth semiconductor member 14 is electrically connected to the second electrode 52.

The fifth semiconductor member 15 is of the second conductivity type. The third semiconductor region 12c is provided between the third partial region 11c and the fifth semiconductor member 15 in the first direction D1. The second semiconductor portion 13b is provided between the fifth semiconductor member 15 and the fourth semiconductor region 12d in the second direction D2. The fifth semiconductor member 15 is electrically connected to the second electrode 52.

A fifth impurity concentration of the second conductivity type of the fifth semiconductor member 15 is lower than a fourth impurity concentration of the second conductivity type of the fourth semiconductor member 14. In one example, the fifth semiconductor member 15 is, for example, a p⁺ layer. In one example, the fourth semiconductor member 14 is, for example, a p⁺⁺ layer.

The third electrode 53 includes a first conductive portion 53a. The fifth partial region 11e is provided between the first partial region 11a and the first conductive portion 53a in the first direction D1.

The first insulating member 41 includes a first insulating region 41a. The first insulating region 41a is provided between the fifth partial region 11e and at least a portion of the first conductive portion 53a.

In the semiconductor device 110, a current flowing between the first electrode 51 and the second electrode 52 can be controlled by a potential of the third electrode 53. The potential of the third electrode 53 may be, for example, a potential based on a potential of the second electrode 52. The first electrode 51 functions as, for example, a drain electrode. The second electrode 52 functions, for example, as a source electrode. The third electrode 53 functions as a gate electrode. The semiconductor device 110 is, for example, a transistor (MOS transistor).

In the semiconductor device 110, the sixth partial region 11f makes Schottky contact with the second electrode 52. A portion including the sixth partial region 11f functions as a Schottky barrier diode (SBD).

For example, a reverse voltage may be applied to the semiconductor device 110. In a state where a reverse voltage is applied, the potential of the second electrode 52 is higher than the potential of the first electrode 51. In this state, when holes are injected from the second electrode 52 into the transistor region, defects or the like may occur in the semiconductor layer 10S, and abnormal characteristics (for example, destruction) may occur. In the semiconductor device 110, by providing the SBD, the hole injection start voltage can be controlled and characteristic abnormalities can be suppressed.

In such a configuration, for example, when the hole injection starting current is high, the surge resistance tends to be low. In the embodiment, the fourth semiconductor member 14 and the fifth semiconductor member 15 having different second conductivity type (p-type) impurity concentrations are provided. Thereby, for example, even when the hole injection starting current is high, a high surge resistance can be maintained. According to the embodiment, a semiconductor device with improved characteristics can be provided. For example, when the hole injection starting current is low, high surge resistance can be maintained.

In the embodiment, a first distance between the fourth semiconductor member 14 and the sixth partial region 11f is preferably shorter than a second distance between the fifth semiconductor member 15 and the sixth partial region 11f. The fourth semiconductor member 14 with a high impurity concentration is provided at a position close to the Schottky contact. The fifth semiconductor member 15 having a relatively low impurity concentration is provided at a position far from the Schottky contact. Thereby, high surge resistance can be maintained more effectively.

For example, the fourth semiconductor member 14 with a high impurity concentration provided near the SBD functions as a hole injection promoting layer. Substantially no operation occurs until hole injection begins. On the other hand, hole injection starts from the fifth semiconductor member 15 that is far from the SBD. After that, a large amount of holes are injected from the fourth semiconductor member 14 that functions as a hole injection promoting layer. Conductivity modulation occurs and resistance decreases. By decreasing the resistance after the start of hole injection, for example, IFSM (peak one cycle surge current) is improved.

The fourth semiconductor member 14, the fifth semiconductor member 15, and the like serve as a current path from the first electrode 51 to the second electrode 52 during transistor operation. By making the characteristics of the current path uniform, stable transistor operation can be easily achieved. For this reason, it is generally not done to make the characteristics (for example, impurity concentration) of the fourth semiconductor member 14 and the fifth semiconductor member 15 different.

The inventor of this application has focused on special circumstances that may occur when an SBD is provided. Focusing on this special situation, the impurity concentrations in the fourth semiconductor member 14 and the fifth semiconductor member 15 are made to be different from each other. Thereby, improvements in properties that are generally not expected can be obtained.

In the embodiment, the semiconductor layer 10S (the first semiconductor member 11, the second semiconductor member 12, the third semiconductor member 13, the fourth semiconductor member 14, the fifth semiconductor member 15, etc.) contains SiC. When the semiconductor layer 10S contains SiC, stacking faults are expanded due to the hole injection. The stacking faults may, for example, change the operating characteristics. By providing the SBD, defects are suppressed. The effects of the fourth semiconductor member 14 and the fifth semiconductor member 15 described above can be effectively obtained.

In the embodiment, the fourth impurity concentration of the second conductivity type in the fourth semiconductor member 14 is higher than the second impurity concentration of the second conductivity type in the second semiconductor member 12. The fifth impurity concentration of the second conductivity type in the fifth semiconductor member 15 is higher than the second impurity concentration. The second semiconductor member 12 is, for example, a p layer. As already explained, the fifth semiconductor member 15 may be a p⁺ layer. The fifth semiconductor member 15 may be a p⁺⁺ layer. The fifth semiconductor member 15 may be a p⁺ layer having a higher impurity concentration than the fourth semiconductor member 14.

In one example of the embodiment, the fourth impurity concentration of the second conductivity type in the fourth semiconductor member 14 may be not less than 1.2 times and not more than 50 times the fifth impurity concentration in the fifth semiconductor member 15.

In one example, the fourth impurity concentration may be not less than 1.8 times and not more than 2500 times the second impurity concentration. The fifth impurity concentration may be not less than 1.5 times and not more than 50 times the second impurity concentration.

In one example, the second impurity concentration is not less than 3×10¹⁶ cm⁻³ and not more than 3×10¹⁹ cm⁻³. In one example, the fourth impurity concentration is not less than 1×10¹⁹ cm⁻³ and not more than 5×10²⁰ cm⁻³. In one example, the fifth impurity concentration is not less than 1×10¹⁸ cm⁻³ and not more than 1×10²⁰ cm⁻³.

In the embodiment, the third impurity concentration of the first conductivity type in the third semiconductor member 13 is higher than the first impurity concentration of the first conductivity type of the first semiconductor member 11. The first semiconductor member 11 is, for example, an n layer. The third semiconductor member 13 is, for example, an n⁺ layer.

In one example, the first impurity concentration may be 1×10¹⁵ cm⁻³ and not more than 1×10¹⁷ cm⁻³. The third impurity concentration may be 1×10¹⁸ cm⁻³ and not more than 5×10²⁰ cm⁻³.

As shown in FIG. 1, the second partial region 11b may be provided between the first partial region 11a and the fourth partial region 11d in the second direction D2.

As shown in FIG. 1, the second electrode 52 may include a first electrode portion 52a and a second electrode portion 52b. The second electrode portion 52b is provided between the sixth partial region 11f and the first electrode portion 52a. The second electrode portion 52b includes at least one selected from the group consisting of Ni, Ti, V, and Mo. With such a second electrode portion 52b, it is easy to obtain the desired Schottky contact.

As shown in FIG. 1, a portion of the first conductive portion 53a of the third electrode 53 may overlap the second semiconductor region 12b and a portion of the first semiconductor portion 13a in the first direction D1.

As shown in FIG. 1, the first insulating member 41 may further include a second insulating region 41b. At least a portion of the second insulating region 41b is provided between the first conductive portion 53a of the third electrode 53 and the second electrode 52.

As shown in FIG. 1, the first semiconductor member 11 may further include a seventh partial region 11g and an eighth partial region 11h. The third partial region 11c is provided between the seventh partial region 11g and the first partial region 11a in the second direction D2. A direction from the seventh partial region 11g to the eighth partial region 11h is along the first direction D1.

The second semiconductor member 12 may further include a fifth semiconductor region 12e. The third semiconductor member 13 may further include a third semiconductor portion 13c. The fifth semiconductor region 12e is provided between the eighth partial region 11h and the fifth semiconductor member 15 in the second direction D2. The fifth semiconductor member 15 is provided between the third semiconductor portion 13c and the second semiconductor portion 13b in the second direction D2.

The third electrode 53 may further include a second conductive portion 53b. The eighth partial region 11h is provided between the seventh partial region 11g and the second conductive portion 53b in the first direction D1.

The first insulating member 41 may further include a third insulating region 41c. At least a portion of the third insulating region 41c is provided between the eighth partial region 11h and at least a portion of the second conductive portion 53b. The second conductive portion 53b functions as a portion of the gate electrode.

The semiconductor device 110 may be provided with a plurality of portions that function as gate electrodes. In one example, the first conductive portion 53a, the second conductive portion 53b, etc. may have a stripe shape along a third direction D3. The third direction D3 crosses a plane including the first direction D1 and the second direction D2. The third direction D3 may be, for example, the Y-axis direction.

In the embodiment, the plurality of portions (such as the first conductive portion 53a and the second conductive portion 53b) that function as gate electrodes may be island-shaped.

The first insulating member 41 may further include a fourth insulating region 41d. At least a portion of the fourth insulating region 41d is provided between the second conductive portion 53b and the second electrode 52.

As shown in FIG. 1, the second semiconductor member 12 may further include a sixth semiconductor region 12f. The third semiconductor member 13 may further include a fourth semiconductor portion 13d. The fourth semiconductor portion 13d is provided between the fourth semiconductor member 14 and the sixth semiconductor region 12f in the second direction D2.

The sixth semiconductor region 12f may be provided, for example, between the fourth semiconductor portion 13d and the sixth partial region 11f.

In the embodiment, the first insulating member 41 may include silicon and a first element including at least one selected from the group consisting of oxygen and nitrogen. The first insulating member 41 may include silicon oxide. The first insulating member 41 may include silicon nitride.

As shown in FIG. 1, the semiconductor device 110 may further include a sixth semiconductor member 16 of the first conductivity type. The sixth semiconductor member 16 is provided between the first electrode 51 and the first semiconductor member 11. A sixth impurity concentration of the first conductivity type in the sixth semiconductor member 16 is higher than the first impurity concentration of the first conductivity type in the first semiconductor member 11. Good electrical connection can be obtained between the first electrode 51 and the semiconductor layer 10S. It becomes easy to obtain low on-resistance.

The semiconductor layer 10S (first semiconductor member 11, second semiconductor member 12, third semiconductor member 13, fourth semiconductor member 14, fifth semiconductor member 15, etc.) may contain. at least one selected from the group consisting of 4H-SiC, 6H-SiC, and 3C-SiC. These semiconductor members include crystals. These semiconductor members may include silicon. These semiconductor members may include a compound semiconductor containing Ga.

For example, the first conductivity type impurity includes at least one selected from the group consisting of N, P, and As. For example, the second conductivity type impurity includes at least one selected from the group consisting of B, Al, and Ga.

In the embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

The embodiments may include the following Technical proposals:

### Technical Proposal 1

A semiconductor device, comprising:
a first electrode;
a second electrode,
a first semiconductor member of a first conductivity type, the first semiconductor member being provided between the first electrode and the second electrode, the first semiconductor member including a first partial region, a second partial region, a third partial region, a fourth partial region, a fifth partial region, and a sixth partial region, a second direction from the third partial region to the second partial region crossing a first direction from the first electrode to the second electrode, the first partial region being provided between the third partial region and the second partial region in the second direction, a direction from the second partial region to the fourth partial region crossing the first direction, a direction from the first partial region to the fifth partial region being along the first direction, a direction from the fourth partial region to the sixth partial region being along the first direction, the sixth partial region being in Schottky contact with the second electrode;
a second semiconductor member of a second conductivity type, the second semiconductor member including a first semiconductor region, a second semiconductor region, a third semiconductor region, and a fourth semiconductor region, a direction from the second partial region to the first semiconductor region being along the first direction, a direction from the third partial region to the third semiconductor region being along the first direction;
a third semiconductor member of the first conductivity type, the third semiconductor member including a first semiconductor portion and a second semiconductor portion, the second semiconductor region being provided between the fifth partial region and the first semiconductor portion in the second direction, the fourth semiconductor region being provided between the second semiconductor portion and the fifth partial region in the second direction, the first semiconductor portion and the second semiconductor portion being electrically connected to the second electrode;
a fourth semiconductor member of the second conductivity type, the first semiconductor region being provided between the second partial region and the fourth semiconductor member in the first direction, the first semiconductor portion being provided between the second semiconductor region and the fourth semiconductor member in the second direction, the fourth semiconductor member being electrically connected to the second electrode;
a fifth semiconductor member of the second conductivity type, the third semiconductor region being provided between the third partial region and the fifth semiconductor member in the first direction, the second semiconductor portion being provided between the fifth semiconductor member and the fourth semiconductor region in the second direction, the fifth semiconductor member being electrically connected to the second electrode, a fifth impurity concentration of the second conductivity type in the fifth semiconductor member being lower than a fourth impurity concentration of the second conductivity type of the fourth semiconductor member;
a third electrode including a first conductive portion, the fifth partial region being provided between the first partial region and the first conductive portion in the first direction; and
a first insulating member including a first insulating region, the first insulating region being provided between the fifth partial region and at least a portion of the first conductive portion.

### Technical Proposal 2

The semiconductor device according to Technical proposal 1, wherein
the fourth impurity concentration is not less than 1.2 times and not more than 50 times the fifth impurity concentration.

### Technical Proposal 3

The semiconductor device according to Technical proposal 1 or 2, wherein
the fourth impurity concentration is higher than a second impurity concentration of the second conductivity type of the second semiconductor member, and
the fifth impurity concentration is higher than the second impurity concentration.

### Technical Proposal 4

The semiconductor device according to Technical proposal 3, wherein
the fourth impurity concentration is not less than 1.8 times and not more than 2500 times the second impurity concentration, ad
the fifth impurity concentration is not less than 1.5 times and not more than 50 times the second impurity concentration.

### Technical Proposal 5

The semiconductor device according to Technical proposal 3 or 4, wherein
the second impurity concentration is not less than 3×10¹⁶ cm⁻³ and not more than 3×10¹⁹ cm⁻³,
the fourth impurity concentration is not less than 1×10¹⁹ cm⁻³ and not more than 5×10²⁰ cm⁻³, and
the fifth impurity concentration is not less than 1×10¹⁸ cm⁻³ and not more than 1×10²⁰ cm⁻³.

### Technical Proposal 6

The semiconductor device according to any one of Technical proposals 1-5, wherein
a first distance between the fourth semiconductor member and the sixth partial region is shorter than a second distance between the fifth semiconductor member and the sixth partial region.

### Technical Proposal 7

The semiconductor device according to any one of Technical proposals 1-6, wherein
the second partial region is provided between the first partial region and the fourth partial region in the second direction.

### Technical Proposal 8

The semiconductor device according to any one of Technical proposals 1-7, wherein
the second electrode includes a first electrode portion and a second electrode portion,
the second electrode portion is provided between the sixth partial region and the first electrode portion, and
the second electrode portion includes at least one selected from the group consisting of Ni, Ti, V, and Mo.

### Technical Proposal 9

The semiconductor device according to any one of Technical proposals 1-8, wherein
a third impurity concentration of the first conductivity type in the third semiconductor member is higher than a first impurity concentration of the first conductivity type in the first semiconductor member.

### Technical Proposal 10

The semiconductor device according to Technical proposal 9, wherein
the first impurity concentration is not less than 1×10¹⁵ cm⁻³ and not more than 1×10¹⁷ cm⁻³, and
the third impurity concentration is not less than 1×10¹⁸ cm⁻³ and not more than 5×10²⁰ cm⁻³.

### Technical Proposal 11

The semiconductor device according to any one of Technical proposals 1-10, wherein
the first insulating member further includes a second insulating region, and
at least a portion of the second insulating region is provided between the first conductive portion and the second electrode.

### Technical Proposal 12

The semiconductor device according to any one of Technical proposals 3-5, wherein
the first semiconductor member further includes a seventh partial region and an eighth partial region,
the third partial region is provided between the seventh partial region and the first partial region in the second direction,
a direction from the seventh partial region to the eighth partial region is along the first direction,
the second semiconductor member further includes a fifth semiconductor region,
the third semiconductor member further includes a third semiconductor portion,
the fifth semiconductor region is provided between the eighth partial region and the fifth semiconductor member in the second direction,
the third electrode further includes a second conductive portion,
the eighth partial region is provided between the seventh partial region and the second conductive portion in the first direction,
the first insulating member further includes a third insulating region, and
at least a portion of the third insulating region is provided between the eighth partial region and at least a portion of the second conductive portion.

### Technical Proposal 13

The semiconductor device according to Technical proposal 12, wherein
the first conductive portion and the second conductive portion are along a third direction, and
the third direction crosses a plane including the first direction and the second direction.

### Technical Proposal 14

The semiconductor device according to Technical proposal 12 or 13, wherein
the first insulating member further includes a fourth insulating region, and
at least a portion of the fourth insulating region is provided between the second conductive portion and the second electrode.

### Technical Proposal 15

The semiconductor device according to any one of Technical proposals 1-14, wherein
the second semiconductor member further includes a sixth semiconductor region,
the third semiconductor member further includes a fourth semiconductor portion, and
the fourth semiconductor portion is provided between the fourth semiconductor member and the sixth semiconductor region in the second direction.

### Technical Proposal 16

The semiconductor device according to Technical proposal 15, wherein
the sixth semiconductor region is provided between the fourth semiconductor portion and the sixth partial region.

### Technical Proposal 17

The semiconductor device according to any one of Technical proposals 1-16, wherein
the first semiconductor member, the second semiconductor member, the third semiconductor member, and the fourth semiconductor member include SiC.

### Technical Proposal 18

The semiconductor device according to any one of Technical proposals 1-17, wherein
the first insulating member includes silicon and a first element including at least one selected from the group consisting of oxygen and nitrogen.

### Technical Proposal 19

The semiconductor device according to any one of Technical proposals 1-8, further comprising:
a sixth semiconductor member of the first conductivity type,
the sixth semiconductor member being provided between the first electrode and the first semiconductor member, and
a sixth impurity concentration of the first conductivity type in the sixth semiconductor member being higher than a first impurity concentration of the first conductivity type of the first semiconductor member.

### Technical Proposal 20

The semiconductor device according to any one of Technical proposals 1-19, wherein
a portion of the first conductive portion overlaps the second semiconductor region and a portion of the first semiconductor portion in the first direction.

According to the embodiments, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode,
a first semiconductor member of a first conductivity type, the first semiconductor member being provided between the first electrode and the second electrode, the first semiconductor member including a first partial region, a second partial region, a third partial region, a fourth partial region, a fifth partial region, and a sixth partial region, a second direction from the third partial region to the second partial region crossing a first direction from the first electrode to the second electrode, the first partial region being provided between the third partial region and the second partial region in the second direction, a direction from the second partial region to the fourth partial region crossing the first direction, a direction from the first partial region to the fifth partial region being along the first direction, a direction from the fourth partial region to the sixth partial region being along the first direction, the sixth partial region being in Schottky contact with the second electrode;
a second semiconductor member of a second conductivity type, the second semiconductor member including a first semiconductor region, a second semiconductor region, a third semiconductor region, and a fourth semiconductor region, a direction from the second partial region to the first semiconductor region being along the first direction, a direction from the third partial region to the third semiconductor region being along the first direction;
a third semiconductor member of the first conductivity type, the third semiconductor member including a first semiconductor portion and a second semiconductor portion, the second semiconductor region being provided between the fifth partial region and the first semiconductor portion in the second direction, the fourth semiconductor region being provided between the second semiconductor portion and the fifth partial region in the second direction, the first semiconductor portion and the second semiconductor portion n being electrically connected to the second electrode;
a fourth semiconductor member of the second conductivity type, the first semiconductor region being provided between the second partial region and the fourth semiconductor member in the first direction, the first semiconductor portion being provided between the second semiconductor region and the fourth semiconductor member in the second direction, the fourth semiconductor member being electrically connected to the second electrode;
a fifth semiconductor member of the second conductivity type, the third semiconductor region being provided between the third partial region and the fifth semiconductor member in the first direction, the second semiconductor portion being provided between the fifth semiconductor member and the fourth semiconductor region in the second direction, the fifth semiconductor member being electrically connected to the second electrode, a fifth impurity concentration of the second conductivity type in the fifth semiconductor member being lower than a fourth impurity concentration of the second conductivity type of the fourth semiconductor member;
a third electrode including a first conductive portion, the fifth partial region being provided between the first partial region and the first conductive portion in the first direction; and
a first insulating member including a first insulating region, the first insulating region being provided between the fifth partial region and at least a portion of the first conductive portion.

2. The device according to claim 1, wherein
the fourth impurity concentration is not less than 1.2 times and not more than 50 times the fifth impurity concentration.

3. The device according to claim 1, wherein
the fourth impurity concentration is higher than a second impurity concentration of the second conductivity type of the second semiconductor member, and
the fifth impurity concentration is higher than the second impurity concentration.

4. The device according to claim 3, wherein
the fourth impurity concentration is not less than 1.8 times and not more than 2500 times the second impurity concentration, ad
the fifth impurity concentration is not less than 1.5 times and not more than 50 times the second impurity concentration.

5. The device according to claim 3, wherein
the second impurity concentration is not less than 3×10¹⁶ cm⁻³ and not more than 3×10¹⁹ cm⁻³,
the fourth impurity concentration is not less than 1×10¹⁹ cm⁻³ and not more than 5×10²⁰ cm⁻³, and
the fifth impurity concentration is not less than 1×10¹⁸ cm⁻³ and not more than 1×10²⁰ cm⁻³.

6. The device according to claim 1, wherein
a first distance between the fourth semiconductor member and the sixth partial region is shorter than a second distance between the fifth semiconductor member and the sixth partial region.

7. The device according to claim 1, wherein
the second partial region is provided between the first partial region and the fourth partial region in the second direction.

8. The device according to claim 1, wherein
the second electrode includes a first electrode portion and a second electrode portion,
the second electrode portion is provided between the sixth partial region and the first electrode portion, and
the second electrode portion includes at least one selected from the group consisting of Ni, Ti, V, and Mo.

9. The device according to claim 1, wherein
a third impurity concentration of the first conductivity type in the third semiconductor member is higher than a first impurity concentration of the first conductivity type in the first semiconductor member.

10. The device according to claim 9, wherein
the first impurity concentration is not less than 1×10¹⁵ cm⁻³ and not more than 1×10¹⁷ cm⁻³, and
the third impurity concentration is not less than 1×10¹⁸ cm⁻³ and not more than 5×10²⁰ cm⁻³.

11. The device according to claim 1, wherein
the first insulating member further includes a second insulating region, and
at least a portion of the second insulating region is provided between the first conductive portion and the second electrode.

12. The device according to claim 3, wherein
the first semiconductor member further includes a seventh partial region and an eighth partial region,
the third partial region is provided between the seventh partial region and the first partial region in the second direction,
a direction from the seventh partial region to the eighth partial region is along the first direction,
the second semiconductor member further includes a fifth semiconductor region,
the third semiconductor member further includes a third semiconductor portion,
the fifth semiconductor region is provided between the eighth partial region and the fifth semiconductor member in the second direction,
the third electrode further includes a second conductive portion,
the eighth partial region is provided between the seventh partial region and the second conductive portion in the first direction,
the first insulating member further includes a third insulating region, and
at least a portion of the third insulating region is provided between the eighth partial region and at least a portion of the second conductive portion.

13. The device according to claim 12, wherein
the first conductive portion and the second conductive portion are along a third direction, and
the third direction crosses a plane including the first direction and the second direction.

14. The device according to claim 12, wherein
the first insulating member further includes a fourth insulating region, and
at least a portion of the fourth insulating region is provided between the second conductive portion and the second electrode.

15. The device according to claim 1, wherein
the second semiconductor member further includes a sixth semiconductor region,
the third semiconductor member further includes a fourth semiconductor portion, and
the fourth semiconductor portion is provided between the fourth semiconductor member and the sixth semiconductor region in the second direction.

16. The device according to claim 15, wherein
the sixth semiconductor region is provided between the fourth semiconductor portion and the sixth partial region.

17. The device according to claim 1, wherein
the first semiconductor member, the second semiconductor member, the third semiconductor member, and the fourth semiconductor member include SiC.

18. The device according to claim 1, wherein
the first insulating member includes silicon and a first element including at least one selected from the group consisting of oxygen and nitrogen.

19. The device according to claim 1, further comprising:
a sixth semiconductor member of the first conductivity type,
the sixth semiconductor member being provided between the first electrode and the first semiconductor member, and
a sixth impurity concentration of the first conductivity type in the sixth semiconductor member being higher than a first impurity concentration of the first conductivity type of the first semiconductor member.

20. The device according to claim 1, wherein
a portion of the first conductive portion overlaps the second semiconductor region and a portion of the first semiconductor portion in the first direction.
